(19) United States
(12) Patent Application Publication
(10) Pub. No.: US 2024/0263302 A1
(43) Pub. Date: Aug. 8, 2024

(54) OXYANIONIC TEMPLATES FOR SURFACE REPLICATION

(71) Applicant: Dickinson Corporation, Novato, CA (US)

(72) Inventors: Matthew Bishop, Novato, CA (US); Abhay V. Thomas, Novato, CA (US); David Andrew Brill, Novato, CA (US)

(73) Assignee: Dickinson Corporation, Novato, CA (US)

(21) Appl. No.: 18/613,847

(22) Filed: Mar. 22, 2024

Related U.S. Application Data
(63) Continuation of application No. 18/338,017, filed on Jun. 20, 2023.
Application No. 18/338,017 is a continuation of application No. PCT/US21/64551, filed on Dec. 21, 2021.
(60) Provisional application No. 63/129,154, filed on Dec. 22, 2020.

(51) Int. Cl. C23C 16/26; B82Y 30/00; B82Y 40/00; C01B 32/186; C23C 16/01; C23C 16/46; C23C 16/56

(52) U.S. Cl. CPC C23C 16/26; B82Y 30/00; B82Y 40/00; C01B 32/186; C23C 16/01; C23C 16/46; C23C 16/56

(57) ABSTRACT

A method of synthesizing a perimorphic framework by chemical vapor deposition of a perimorph around an oxyanionic template, followed by dissolution of the oxyanionic template in water or in an aqueous weak acid comprising an oxyanion.

### RELATED APPLICATIONS

This application is a bypass continuation of PCT/US2021/64551, filed on Dec. 21, 2021, which claims priority to U.S. Provisional Patent Application No. 63/129,154, filed Dec. 22, 2020, the entire disclosure of which is incorporated herein by reference. The following applications are hereby incorporated by reference in their entirety for all purposes: PCT/US21/53316 (the '53316 Application); PCT/US21/49195 (the '49195 Application); U.S. Provisional Patent Application 63/075,918 (the '918 Application); U.S. Provisional Patent No. 63/086,760 (the '760 Application); U.S. Provisional Patent Application 63/121,308 (the '308 Application); U.S. Utility application Ser. No. 16/758,580 (the '580 Application); U.S. Utility application Ser. No. 16/493,473 (the '473 Application); PCT/US17/17537 (the '17537 Application); PCT/US21/37435 (the '37435 Application); U.S. Provisional Patent Application 63/129,154 (the '154 Application) and U.S. Pat. No. 10,717,843 B2 (the '843B2 Patent).

### FIELD OF DISCLOSURE

The following disclosure relates to novel templates used to synthesize perimorphic materials via surface replication. The templates possess reactive surface sites that may catalyze the decomposition of certain molecular adsorbates, while also possessing bulk phases that are more soluble than the refractory metal oxides often utilized in surface replication procedures.

### BACKGROUND

Recently, we showed in the '53316 Application how “surface replication” procedures could be performed in a way that conserved process materials and process liquids. In particular, we described the use of chemical vapor deposition (“CVD”) to adsorb a “perimorphic” material around a templating surface—i.e. the surface of a template structure. Upon formation of the perimorphic material, the endomorphic template structure could then be extracted via dissolution and reconstituted via a solventless precipitation.

Refractory oxides, the surface defects of which may catalyze nucleation of a perimorphic phase during chemical vapor deposition, are an important class of template materials in the '53316 Application. Refractory oxides possess excellent thermal stability for high-temperature CVD. In spite of these advantages, many refractory oxides may be insoluble or minimally soluble, complicating endomorphic extraction and template recycling.

The desire for higher-solubility templates for CVD procedures has been addressed in the prior art by utilizing NaCl templates. Unlike oxide templates, though, NaCl templates do not appear to catalyze CVD nucleation of a perimorphic phase unless the templating surface is at least partially molten if only locally at corners or edges. Nucleation at these molten sites is theorized to involve inelastic collisions and dissociation of reactive gas molecules. After synthesizing the perimorphic material, the endomorphic NaCl templates may be extracted by dissolving them in water. While NaCl templates provide greater template solubility than metal oxides, molten templates may prove problematic at scale. It is expected, for instance, that NaCl template particles with partially molten surfaces would be corrosive and would cohere to one another.

Therefore, the library of template materials demonstrated in the '53316 Application also includes certain oxyanion-bearing, solid-state salts that offer higher solubility and easier scalability. As an example, we used an epsomite (MgSO₄·7H₂O) template precursor material to form a basic magnesium sulfate (MgSO₄) template material, which was then utilized to nucleate and grow a perimorphic carbon material in a template-directed CVD procedure. The endomorphic template material was then extracted via dissolution in water.

### SUMMARY

In the '37435 and '53316 Applications, we explored a specific type of template-directed chemical vapor deposition involving the nucleation and growth of what workers have termed a free radical condensate (“FRC”). From this FRC, synthetic “anthracitic networks” (named for their structural similarity to anthracite, which is crosslinked via structural dislocations) with various chemical compositions can be formed around a templating surface, which directs their morphology. Template-directed FRC growth and synthesis of anthracitic networks may be performed at low CVD temperatures, provided the FRC can be nucleated.

In the present disclosure, we demonstrate an expanded library of new, oxyanion-bearing template materials that may be utilized to synthesize perimorphic materials—and specifically to synthesize perimorphic materials comprising a synthetic anthracitic network. Some of these template materials may be less thermally stable than refractory metal oxides but are sufficiently stable for use in template-directed CVD procedures in which FRC nucleation and growth can occur with practical kinetics.

This library of new template materials are shown to catalyze the nucleation and growth, via CVD, of perimorphic materials. They also comprise salts, and especially oxyanion-bearing salts, that are more readily dissolved than many refractory oxides. This makes these template materials potentially beneficial for surface replication procedures, such as those described in the '53316 Application, where template materials and process liquids are conserved.

The oxyanion-bearing templates presented herein represent exemplary specimens of a novel category of templates. It is anticipated that many other variants may be synthesized without deviating from the invention. Likewise, the perimorphic materials presented herein represent exemplary versions of perimorphic materials that can be synthesized on these templates. Other perimorphic materials, such as those demonstrated in the '53316 Application, may be synthesized on these templates without deviating from the invention.

Additional advantages and applications will be readily apparent to those skilled in the art from the following detailed description. The examples and descriptions herein are to be regarded as illustrative in nature and not restrictive.

### BRIEF DESCRIPTION OF THE FIGURES

Exemplary embodiments are described with reference to the accompanying figures, in which:

FIG. 1: Illustration representing the process of surface replication, starting with defect-catalyzed nucleation on the templating surface, followed by conformal growth over the templating surface.

FIG. 2: SEM images of the K₂SO₄ oxyanionic template precursor powder.

FIG. 3: SEM images of perimorphic composite structures created by growing perimorphic carbon on oxyanionic templates.

FIG. 4: SEM images of crumpled perimorphic frameworks comprising graphenic carbon.

FIG. 5: Optical micrograph of MgSO₄-7H₂O template precursor crystals.

FIG. 6: SEM images of perimorphic composite structures created by growing perimorphic carbon on oxyanionic templates.

FIG. 7: SEM images of carbon perimorphic frameworks synthesized on porous, oxyanionic templates.

FIG. 8: Average Raman spectra of carbon perimorphic frameworks generated in Experiments 1-5.

FIG. 9: Unsmoothed and smoothed average Raman spectrum of carbon perimorphic frameworks generated in Experiment 3.

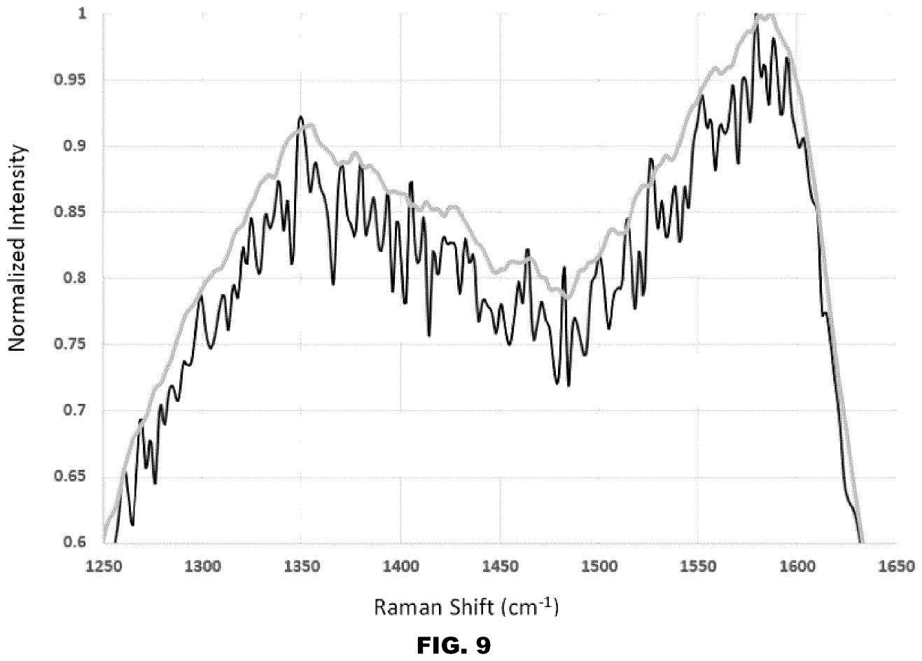

FIG. 10: SEM image of perimorphic composite structures synthesized in Experiment 3.

FIG. 11: SEM images buckypaper and sheet-like, crumpled perimorphic fragments produced via growth on Li₂CO₃ template.

FIG. 12: TEM images of sheet-like, crumpled perimorphic fragments produced via growth on Li₂CO₃ template. Individual graphenic lattices within the perimorphic wall are traced.

### DETAILED DESCRIPTION

### Terms and Concepts

A “template,” as defined herein, is a potentially sacrificial structure that imparts a desired morphology to another material formed in or on it. Of relevance for surface replication techniques are the template's surface (i.e. the “templating surface”), which is positively replicated, and its bulk phase (i.e. the “templating bulk”), which is negatively replicated. The template may also perform other roles, such as catalyzing the formation of the perimorphic material. A “templated” structure is one that replicates some feature of the template.

A “perimorph” or “perimorphic” material is a material formed in or on a substantially solid-state or “hard” template material.

“Surface replication,” as defined herein, comprises a templating technique in which a template's surface is used to direct the formation of a thin, perimorphic wall of adsorbed material, the wall substantially encapsulating and replicating the templating surface upon which it is formed. Subsequently, upon being displaced, the templating bulk is replicated, in negative, by an endocellular space within the perimorphic wall. Surface replication creates a perimorphic framework with a templated pore-and-wall architecture.

A “perimorphic framework” (or “framework”), as defined herein, is the nanostructured perimorph formed during surface replication. A perimorphic framework comprises a nanostructured “perimorphic wall” (or “wall”) that may range from less than 1 nm to 100 nm in thickness but is preferably between 0.6 nm and 5 nm. Insomuch as it substantially encapsulates and replicates the templating surface, the perimorphic wall can be described as “conformal.” Perimorphic frameworks may be made with diverse architectures, ranging from simple, hollow architectures formed on nonporous templates to labyrinthine architectures formed on porous templates. They may also comprise different chemical compositions. A typical framework may be constructed from carbon and may be referred to as a “carbon perimorphic framework.”

An “endomorph,” as defined herein, comprises a template as it exists within a substantially encapsulating perimorphic phase. Therefore, after the perimorphic phase has been formed around it, the template may be described as an endomorph, or as “endomorphic.”

A “perimorphic composite,” or “PC” material, as defined herein, is a composite structure comprising an endomorph and a perimorph. A PC material may be denoted x@y, where x is the perimorphic element or compound and y is the endomorphic element or compound. For example, a PC structure comprising a carbon perimorph on an MgO endomorph might be denoted C@MgO.

The term “cellular” is used herein to describe the pore-and-wall morphology associated with perimorphic frameworks. A “cell” or “cellular subunit” comprises a specified endocellular pore and region of the perimorphic wall around the pore.

The term “endocellular” is used herein to describe a negative space in a perimorphic framework that is formed by the displacement of the endomorph from the perimorphic composite. Like the endomorph whence it derives, the endocellular space is substantially encapsulated by the perimorphic wall.

The term “exocellular” is used herein to describe a negative space in a perimorphic framework that is inherited from the pore space of the perimorphic composite, which is in turn inherited from the pore space of a porous template. We note that an exocellular space, despite the “exo-” prefix, maybe located substantially inside a perimorphic framework.

A perimorphic framework's endocellular and exocellular spaces are substantially separated by the perimorphic wall. However, the ability to displace the endomorph from the template composite implies that the wall is somewhere open or an incomplete barrier, since a perfectly encapsulated endomorph could not be displaced. Therefore, while a perimorph is herein described as substantially encapsulating a templating surface, the encapsulation may nevertheless be incomplete or subject to breach.

The term “native” is used herein to describe the morphological state of a perimorphic structure in the perimorphic composite. A “native” feature comprises a feature that is substantially in its native state, and we may refer to a structure as “natively” possessing some feature (e.g. a perimorphic wall that is natively 1 nm thick). After displacement of the endomorph from the perimorphic composite, the perimorph may either substantially retain its native characteristics, or it may be altered.

The term “non-native” is used herein to describe a morphological state of a perimorphic structure that is substantially altered from its native morphological state (i.e. its original state in the perimorphic composite). This alteration may occur at the substructural or superstructural levels. For example, during evaporative drying of an internal liquid, a perimorphic wall may be pulled inward by the liquid, collapsing a portion of the endocellular space. A framework's deformation into a non-native, collapsed morphology may be reversible—i.e. the framework may be able to substantially recover its native morphology.

A “template precursor,” or “precursor,” as defined herein, is a material from which a template is derived via some treatment that may comprise decomposition, grain growth, and sintering. A template may retain a pseudomorphic resemblance to the template precursor; therefore, engineering the precursor may offer a way to engineer the template.

The term “superstructure” is herein defined as the overall size and geometry of a porous template or perimorphic framework. A perimorphic framework's superstructure may be inherited from the morphology of the template precursor. The superstructure of a perimorphic framework is important because the overall size and geometry of a framework will influence its properties, including how it interacts with other particles.

The term “substructure” is herein defined as the localized morphology—i.e. the internal architecture—of a porous template or perimorphic framework. Certain porous templates or perimorphic frameworks have a substructure comprising repeating, conjoined substructural units, or “subunits.” Different substructures may be characterized by subunits of different shapes, sizes, and spacings from one another.

“Endomorphic extraction,” as defined herein, comprises the selective removal of a portion of an endomorph from a perimorphic composite. Endomorphic extraction comprises a reaction between an endomorph and an extractant solution that produces solvated ions that are exfiltrated from the surrounding perimorph, resulting in concurrent displacement of the endomorph, consumption of the extractant from the extractant solution, and generation of a stock solution. Generally, the removal of substantially all of an endomorph's mass is desired. Occasionally, the partial removal of an endomorph's mass may be desired, or only partial removal of an endomorph's mass nay be achievable.

“Perimorphic separation,” as defined herein, comprises the separation of a perimorphic product after endomorphic extraction from non-perimorphic, conserved process materials. Conserved, non-perimorphic phases may comprise process liquid, stock solution, and precipitates of the stock solution. Perimorphic separation may comprise many different industrial separation techniques, (e.g. filtration, centrifugation, froth flotation, solvent-based separations, etc.).

The “General Method” is the most basic form of the method described in the '53316 Application. It comprises a method for synthesizing a perimorphic product wherein substantial portions of the template material and the process liquid are conserved and may be reused. As such, the General Method may be performed cyclically.

The General Method comprises a series of steps that is herein presented, for ease of description, in 4 stages (i.e. the Precursor Stage, Template Stage, Replication Stage, and Separation Stage). Each stage is defined according to one or more steps, as described below:
Precursor Stage: A precursor material is derived from a stock solution via solventless precipitation. A portion of the process liquid is conserved.
Template Stage: The precursor material formed in the Precursor Stage is treated in one or more procedures to form a template material.
Replication Stage: An adsorbate material is adsorbed to the templating surface of the template to form a PC material.
Separation Stage: Endomorphic extraction and perimorphic separation are performed. Endomorphic extraction produces a stock solution. Perimorphic separation separates the perimorphic product from conserved process materials.

The term “graphenic,” as used herein, describes a two-dimensional, polycyclic structure of sp²-hybridized or sp³-hybridized atoms. While graphene denotes a form of carbon, we utilize the term “graphenic” herein to describe a variety of graphene polymorphs (including known or theorized polymorphs such as graphene, amorphous graphene, phagraphene, haeckelites, etc.), as well as to describe other two-dimensional graphene analogues (e.g. atomic monolayers of BN, BCₓN, etc.) Hence, the term “graphenic” is intended to encompass any hypothetical polymorph meeting the basic criteria of two-dimensionality, polycyclic organization and sp² or sp³ hybridization.

“Two-dimensional” herein describes a molecular-scale structure comprising a single layer of atoms. A two-dimensional structure may be embedded or immersed in a higher-dimensional space to form a larger-scale structure that, at this larger scale, might be described as a three-dimensional. For instance, a graphenic lattice of subnanoscopic thickness might curve through three-dimensional space to form the atomically thin wall of a nanoscopically three-dimensional cell. This cell would still be described two-dimensional at the molecular scale.

An “sp^{x} ring” is herein defined as a polyatomic ring comprising atomic members that do not all share the same orbital hybridization—e.g., some atoms may be sp²-hybridized and some may be sp³-hybridized.

“Sp² grafting” is herein defined as the formation of a sp²-sp² bond line between edge atoms of two laterally adjacent graphenic structures. Sp² grafting across a tectonic interface creates sp² ring-connections that may cause distinct graphenic structures to become ring-connected and coalesce into a larger graphenic structure.

“Sp³ grafting” is herein defined as the formation of sp³-sp³ bonds between edge atoms of two laterally adjacent graphenic structures. This may involve the sp²-to-sp³ rehybridization of sp² edge atoms. Sp³ grafting across a tectonic interface creates sp^{x} rings that may cause distinct graphenic structures to become ring-connected and coalesce into a larger graphenic structure.

A “Y-dislocation” is herein defined as a ring-connected, Y-shaped graphenic region formed by a layer's bifurcation into a laterally adjacent bilayer. The two “branches” of the Y-shaped region comprise z-adjacent sp^{x} rings, which together comprise a diamondlike seam situated at the interface between the laterally adjacent layer and bilayer. The characteristic Y-shaped geometry is associated with a cross-sectional plane of the layers and the diamondlike seam. Y-dislocations are described more comprehensively in the '37435 Application.

An “anthracitic network” is herein defined as a type of layered graphenic network comprising two-dimensional molecular structures crosslinked via certain characteristic structural dislocations, described herein as “anthracitic dislocations,” which include Y-dislocations, screw dislocations, and mixed dislocations having characteristics of both Y-dislocations and screw dislocations. Z-adjacent layers in anthracitic networks exhibit nematic alignment. Anthracitic networks are described more comprehensively in the '37435 Application.

“Nematic alignment” is herein used to describe a molecular-scale, general xy-alignment between z-adjacent layers in a multilayer graphenic system. This term is typically used to denote a type of consistent but imperfect xy-alignment observed between liquid crystal layers, and we find it useful herein for describing the imperfect xy-alignment of z-adjacent layers in anthracitic networks. Nematic alignment may be characterized by a significant presence of <002> interlayer d-spacings larger than 3.50 Å.

An “sp^{x} network” is herein defined as a type of synthetic anthracitic network comprising a single, continuous graphenic structure, wherein the network is laterally and vertically crosslinked via diamondlike seams and mixed dislocations (e.g. chiral columns). In the context of maturation processes, an sp^{x} network may be described as an “sp^{x} precursor.” Sp^{x} networks are described more comprehensively in the '37435 Application.

In the present disclosure, Raman spectral analysis may involve reference to unfitted or fitted spectral features. “Unfitted” spectral features pertain to spectral features apparent prior to deconvolution via profile-fitting software. Unfitted features may therefore represent a convolution of multiple underlying features, but their positions are not subjective. “Fitted” spectral features pertain to the spectral features assigned by profile-fitting software. Imperfect profile fitting indicates the potential presence of other underlying features that have not been deconvoluted. A fitted peak P is designated Pf. An unfitted peak P is designated Pᵤ.

Carbon sp^{x} networks can be further classified based on the extent of their internal grafting, which can be determined by the prevalence of its sp²-hybridized edge states prior to maturation. With respect to the extent of this grafting, a carbon sp^{x} network can be described as:
“Minimally grafted” if (a) its average Dᵤ position is located above 1342 cm⁻¹, (b) its average D_{f} peak position is located below 1342 cm⁻¹ and (c) no point spectra exhibit Dᵤ peak positions below 1342 cm⁻¹
“Partially grafted” if (a) its average Dᵤ peak position is located between 1332 cm⁻¹ and 1342 cm⁻¹ and (b) no point spectra reveal Dᵤ peak positions below 1332 cm⁻¹; or alternatively if (a) its average Dᵤ peak position is located above 1342 cm⁻¹ and (b) point spectra exhibit Dᵤ peak positions between 1332 cm⁻¹ and 1340 cm⁻¹.
“Highly grafted” if its average Dᵤ peak position is located below 1332 cm⁻¹, or alternatively if (a) its average Dᵤ peak position is located above 1332 cm⁻¹ and (b) some point spectra exhibit localized Dᵤ peak positions below 1332 cm⁻¹.

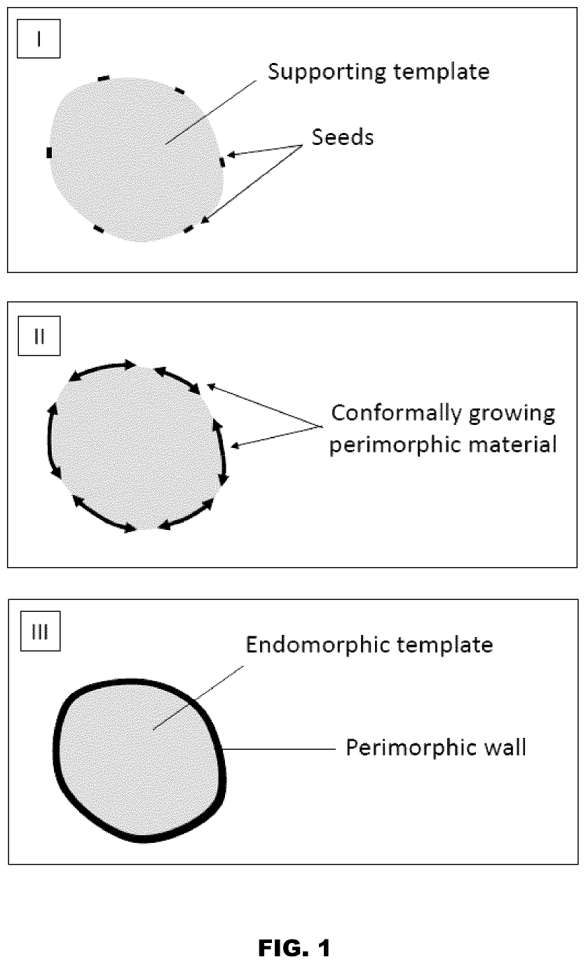

A “helicoidal network” is herein defined as a type of synthetic anthracitic network comprising screw dislocations. These screw dislocations may be formed via the maturation of chiral columns present in sp^{x} networks. Hence, an sp^{x} network may be described as an “sp^{x} precursor” of a helicoidal network. The derivation of helicoidal networks from sp^{x} precursors is indicated by the dotted arrow labeled “maturation” in the classification chart in FIG. 1.

“Maturation” is herein defined as a structural transformation that accompanies the sp³-to-sp² rehybridization of sp³-hybridized states in an sp^{x} precursor. Maturation of an sp^{x} precursor ultimately forms a helicoidal network; the extent of maturation is determined by the degree to which the sp³-to-sp² rehybridization is completed. Maturation is progressive, so networks in intermediate states comprising both sp^{x} and helicoidal network features may be formed. Additionally, maturation may be localized; for instance, heating certain locations of the network, such as by laser, might cause localized maturation of the affected area.

A “highly mature” carbon helicoidal network is defined herein as a carbon helicoidal network having an average Dᵤ peak position that is at least 1340 cm⁻¹ and is at least 8 cm⁻¹ higher than that of its sp^{x} precursor.

An “x-carbon” is herein defined as a category of synthetic anthracitic networks constructed from graphene and comprising one of the following:
an “x-sp^{x} network,” defined herein as a highly grafted sp^{x} network
a “helicoidal x-carbon” formed by maturing an x-sp^{x} precursor to either an intermediate or highly mature state

A “z-carbon” is herein defined as a category of synthetic anthracitic networks constructed from graphene and comprising one of the following:
a “z-sp^{x} network,” defined as a minimally or partially grafted sp^{x} network
a “helicoidal z-carbon” formed by maturing a z-sp^{x} precursor to either an intermediate or highly mature state.

“Oxyanionic templates” are defined herein as templates that comprise at least one oxyanion-bearing compound as a substantial fraction of their overall composition. It is noted that oxyanionic templates may also comprise oxide sites or phases. For example, an otherwise pure oxyanionic template may comprise superficial oxide sites that provide a catalytic function, under CVD conditions, similar to the catalytic function of the oxide sites on the surface of an oxide template. Nevertheless, insomuch as its overall composition differs from an oxide, an oxyanionic template may be preferable in other ways for certain applications where its template morphology is suitable. A chief difference may be its solubility, or the solubility of a compound that may be readily formed upon exposure of the oxyanionic template to water during endomorphic extraction of the template.

“A reactive site” is defined herein as a site found on the templating surface of a template that is capable of catalyzing the nucleation of a perimorphic material during CVD. Without reactive sites, it may not be possible to nucleate or grow a perimorphic wall on the templating surface during CVD without seeding via a catalytic adsorbate. A templating surface's reactive sites may comprise high-energy defects (e.g. step sites on metal oxide templating surfaces) or other reactive sites.

Without being bound by theory, we hypothesize that CVD growth on oxyanionic templates proceeds in a similar fashion to CVD growth on metal oxide templates. Namely, the perimorphic wall nucleates via dissociative adsorption of reactive gas molecules at reactive sites, which may comprise oxygen anions present on the templating surface. From these nuclei, the perimorphic wall may then grow conformally over the templating surface, substantially encapsulating the endomorphic template and resulting in surface replication, as described in the '53316 Application and illustrated in FIG. 1. Optionally, the perimorphic wall formed may comprise a synthetic anthracitic network—i.e. a layered, crosslinked architecture constructed from two-dimensional molecular structures such as graphenic structures. The endomorphic template may then be extracted via dissolution in a liquid. Endomorphic extraction may result in a perimorphic framework.

It is to be understood that, in practice, just like the exemplary templates that have been described in the '53316 Application, oxyanionic templates may be synthesized in many different shapes and sizes.

### Template Considerations

A template utilized in CVD surface replication may be required to fulfill a number of different requirements, including:

1. The template may be required to catalyze nucleation of a perimorphic phase at one or more reactive sites. From the resulting nucleus or nuclei, a free radical condensate may then be grown over the templating surface. This free radical condensate may autocatalyze its own growth, with the underlying surface directing its morphology. The chemical nature of the reactive sites, their level of activity or inactivity, and their areal density on the templating surface may vary based upon numerous factors including the template's chemical composition, the reactive gases utilized in the CVD procedure, and the CVD conditions.

2. The template may be required to remain substantially solid-state under a CVD condition needed for the synthesis of a desired perimorphic material, with no melting or minimal melting of the templating surface or bulk. This may be especially important if the form of template material comprises a powder of many individual template structures. Such powders, if melted, may become difficult to handle as individual template particles come into contact and cohere to one another. A molten template may also form slag on or corrode a vessel holding it.

3. Depending on application requirements, the template may be required to have a specific, engineered morphology that it will impart to the perimorphic material synthesized on it. Therefore, it may often be desirable that the template comprise either a precipitate (or derivative thereof), since precipitation may enable a specific template morphology to be engineered.

4. The template may be required to be either reasonably water-soluble, or to form a reasonably water-soluble product when exposed to water or to an aqueous oxyanion-containing solution (e.g. carbonic acid). This may facilitate the retention and recycling of the template material, as well as the preservation of process water, as described in the '53316 Application.

To meet these requirements for each of the many applications that might be encountered, it is helpful to have recourse to a broader library of CVD template options than can be found among oxides, which tend to be less soluble than might be desired, and halides, which tend to be less thermally stable than might be desired.

### Diverse Mechanisms for Nucleation

Nucleation mechanisms are difficult to characterize due in part to the complexity and diversity of CVD reactions and the participating chemical species. Any nucleation or growth mechanism, whether fully characterized herein or not, should be considered within the scope of the present disclosure.

It has been generally agreed that, during CVD on oxide templates, perimorphic carbon species nucleate at high-energy surface defects (e.g. step-sites). On other template materials, nucleation mechanisms may be fundamentally different. For example, nucleation on metallic templates may require carbon to be first dissolved into the metal, then precipitated, while nucleation on metal halide templates may require molten surfaces where inelastic collisions with gaseous molecules occur. Mechanisms pertaining to one category of templates do not necessarily apply to the others; for instance, surface defects on the solid-state surfaces of NaCl templates have not been shown to be catalytically inactive.

Other than our recent work in the '53316 Application, where perimorphic growth was accomplished on oxyanionic templates, nucleation at surface defects has only been observed on oxides.

### Analytical Techniques and Furnace Scheme

Thermogravimetric analysis (TGA) was used to analyze the thermal stability and composition of materials. All TGA characterization was performed on a TA Instruments Q600 TGA/DSC. A 90 μL alumina pan was used to hold the sample during TGA analysis. All analytical TGA procedures were performed at 20° C. per min unless otherwise mentioned. Either air or Ar (Ar) was used as the carrier gas during analytical TGA procedures unless otherwise mentioned.

Raman spectroscopy was performed using a ThermoFisher DXR Raman microscope equipped with a 532 nm excitation laser. For each sample analyzed, 16 point spectra were generated using measurements taken over a 4×4 point rectangular grid. The normalized point spectra were then averaged to create an average spectrum, with any point spectra indicating a poor signal being excluded from the average. The Raman peak intensity ratios and Raman peak positions reported for each sample all derive from the sample's average spectrum. No profile fitting software was utilized, so the reported peak intensity ratios and peak positions relate to the unfitted peaks pertaining to the overall Raman profile. All samples comprised dried carbonaceous powders resulting from endomorphic extraction and rinsing.

The furnace scheme utilized for all experiments was as follows. The furnace used was an MTI rotary tube furnace with a maximum programmable temperature of 1200° C. The furnace had a 60 mm quartz reactor tube with a gas feed inlet. The opposite end of the tube was left open to the air. The furnace was kept level throughout deposition. Experimental materials in powder form were placed in ceramic boats, and the boats were placed in the center of the quartz tube (in the furnace's heating zone). The quartz tube was not rotated during deposition.

### EXPERIMENTS AND ANALYSIS

Five experiments are described below. For each of these experiments there are unique template precursor materials, template materials, perimorphic composite materials, and perimorphic materials.

For exemplary purposes, in each of the experiments perimorphic carbons were formed on the templates. However, other perimorphic materials might be nucleated and grown without deviating from the invention.

The template precursor materials include potassium carbonate (Experiments 1 and 2), potassium sulfate (Experiment 3), lithium sulfate (Experiment 4), and magnesium sulfate (Experiment 5). To produce these precursor materials, commercially sourced potassium carbonate, potassium sulfate, lithium sulfate, and magnesium sulfate powders were first dissolved in H₂O at approximately room temperature. Either isopropanol or acetone was then added dropwise while stirring to induce precipitation of the solute. The precipitate was filtered and then dried to form a powder. Table 1 below presents the specific details of each template precursor precipitation.

TABLE 1
Template precursor formation details for Experiments 1-5

| | | | | | | Mass |
|---|---|---|---|---|---|---|
| | | | Mass | | | of |
| | | | of | DI | | Sol- |
| Exper- | Precursor | Melting | Solute | H₂O | | vent |
| iment | Type | point | (g) | (g) | Solvent | (g) |
| 1 | Potassium | 1069° C. | 9.94 | 100 | Isopropanol | 101 |
| | Sulfate | | | | | |
| 2 | Potassium | 1069° C. | 50.015 | 500 | Isopropanol | 500 |
| | Sulfate | | | | | |
| 3 | Potassium | 891° C. | 150.004 | 150 | Isopropanol | 667 |
| | Carbonate | | | | | |
| 4 | Lithium | 859° C. | 51.000 | 150 | Acetone | 604 |
| | Sulfate | | | | | |
| 5 | Magnesium | 1124° C. | 100.06 | 100 | Acetone | 411 |
| | Sulfate | | | | | |

The template precursor materials in Experiments 1 and 2 comprise the same compound (K₂SO₄). These precursor samples differed only with respect to the batch size, with the batch size in Experiment 2 being roughly 5 times larger than the batch size in Experiment 1.

In the next stage of the experiments, summarized in Table 2 below, each of the template precursor samples was placed in the tube furnace previously described. Each template precursor powder was then heated to the CVD temperature under 1100 seem of flowing Ar gas, whereupon propylene (C₃H₆) gas flow was commenced. The powder at this temperature, and under this atmosphere of flowing Ar and C₃H₆, comprised the template material in each experiment.

During CVD, perimorphic composite materials were formed by nucleating and growing perimorphic carbon on the templating surfaces. Similar CVD surface replication procedures have been described in the '53316 Application. In each experiment presented herein, the CVD temperature was at least 279° C. below the melting point of the template precursor material. No signs of melting were observed microscopically or macroscopically, including after the CVD procedure. Experimental parameters during CVD are shown in Table 2 below:

TABLE 2
Experimental details of CVD surface replication for Experiments 1-5.

| | | Initial | Final | CVD | | | | | |
|---|---|---|---|---|---|---|---|---|---|
| | Chemical | Mass | Mass | Temp. | Time | | Flow | | Flow |
| Experiment | Formula | (g) | (g) | (° C.) | (min) | Gas 1 | (sccm) | Gas 2 | (sccm) |
| 1 | K₂SO₄ | 3.9396 | — | 650 | 30 | C₃H₆ | 1270 | Ar | 1100 |
| 2 | K₂SO₄ | 2.1639 | 2.1565 | 580 | 120 | C₃H₆ | 1150 | Ar | 1100 |
| 3 | K₂CO₃ | 7.4404 | 6.5665 | 580 | 120 | C₃H₆ | 1150 | Ar | 1100 |
| 4 | Li₂SO₄ | 3.0589 | 3.0088 | 580 | 120 | C₃H₆ | 1150 | Ar | 1100 |
| 5 | MgSO₄ | 3.4571 | 2.6162 | 580 | 120 | C₃H₆ | 1150 | Ar | 1100 |

As shown in Table 2, CVD parameters were similar for all experiments except Experiment 1 (K₂SO₄). For Experiment 1, the flow rate for C₃H₆ was significantly higher (1270 sccm) than it was for Experiments 2 through 5. The flow rates were changed to test deposition conditions under different chemical environments and different exposures. Experiment 1 was also run at a higher temperature (650° C.), but for a shorter duration (i.e., 30 minutes, as opposed to 120 minutes). Experiments 2 through 5 were run at 580° C. for 120 minutes, using a C₃H₆ flow rate of 1100 sccm. The resulting perimorphic composite powders, comprising both an endomorphic template phase and a perimorphic carbon phase, were weighed for comparison with the initial mass of the template precursor powder prior to heating. The final mass is the mass of the perimorphic composite, comprising both the endomorphic template and the perimorphic carbon.

In each experiment, the powder retrieved from the furnace had nucleated and grown a carbonaceous perimorphic wall. There were no signs that nucleation that occurred on the templating surface was unrelated to melting. Nucleation on molten areas of the templating surface, such as the molten edges and corners of NaCl particles, produces heterogeneous perimorphic compositions that can be discerned via SEM and Raman analysis. In such particles, different perimorphic carbon compositions may be observed in areas where the templating surface was molten compared to areas where the templating surface was solid. Nucleation due to absorption or dissolution of carbon in these non-metallic templates can also be ruled out. We therefore attribute nucleation primarily to dissociative adsorption at reactive sites on the templating surface, as has been observed for metal oxide templates.

The exact nature of the reactive sites on the surfaces of these oxyanionic templates is unknown, and it is unknown whether the templates were purely oxyanionic in chemical composition or may have also comprised oxygen anions on their surfaces due to minor levels of decomposition. However, given the extremely small mass losses that were recorded for the anhydrous sulfate samples in Experiments 1, 2, and 4, some of which can be attributed to adsorbed water, and given additionally that some of these sulfates melt prior to thermally decomposing (e.g. Li₂SO₄), and given lastly the almost negligible additional mass contributed by the perimorphic carbon (the perimorphic wall comprising only a few graphenic layers), we can conclude that the extent of any decomposition was minor. For instance, K₂SO₄ thermally decomposes around 750° C. in the presence of a carbonaceous reducing agent. While it is possible that some minor decomposition occurred at 580° C., the templates in Experiment 1 and 2 were substantially K₂SO₄ in terms of chemical composition.

Endomorphic extraction of the oxyanionic templates from the perimorphic composite structures was performed in each experiment by dissolving the template in water, which was accomplished easily in small volumes of water, further corroborating the solubility of the oxyanionic templates. The resulting perimorphic frameworks were then rinsed to minimize residual ions upon drying. At this stage, an immiscible solvent such as ethyl acetate might also be utilized to separate the perimorphic carbon from the aqueous process liquid in order to reduce or eliminate the need for rinsing, as described in the '53316 Application.

SEM analysis was performed to provide a general understanding of the template and perimorphic carbon materials. Specifically, we analyze template precursor materials, PC materials, and perimorphic frameworks from Experiments 1 and 5. For the sake of brevity, and because the present disclosure focuses on the ability to synthesize the perimorphic material on the template, rather than on each template's specific morphological features (which can be varied widely based on the precipitation processes utilized to make them), we do not report SEM analysis for all of the samples.

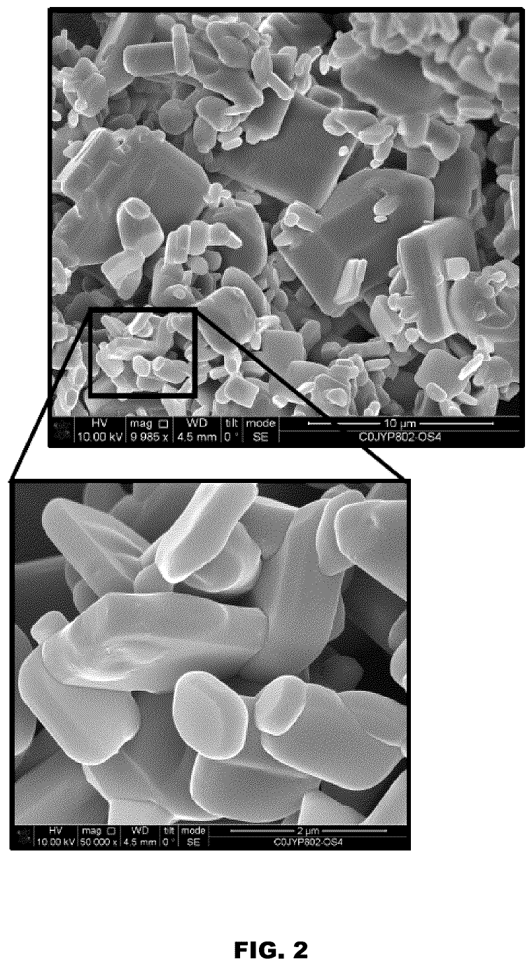

FIG. 2 includes an SEM micrograph showing the template precursor powder used in Experiment 1. The powder comprises some morphological variety, with most crystals adopting a thick, slab-like morphology. Many of the particles are polycrystalline agglomerates.

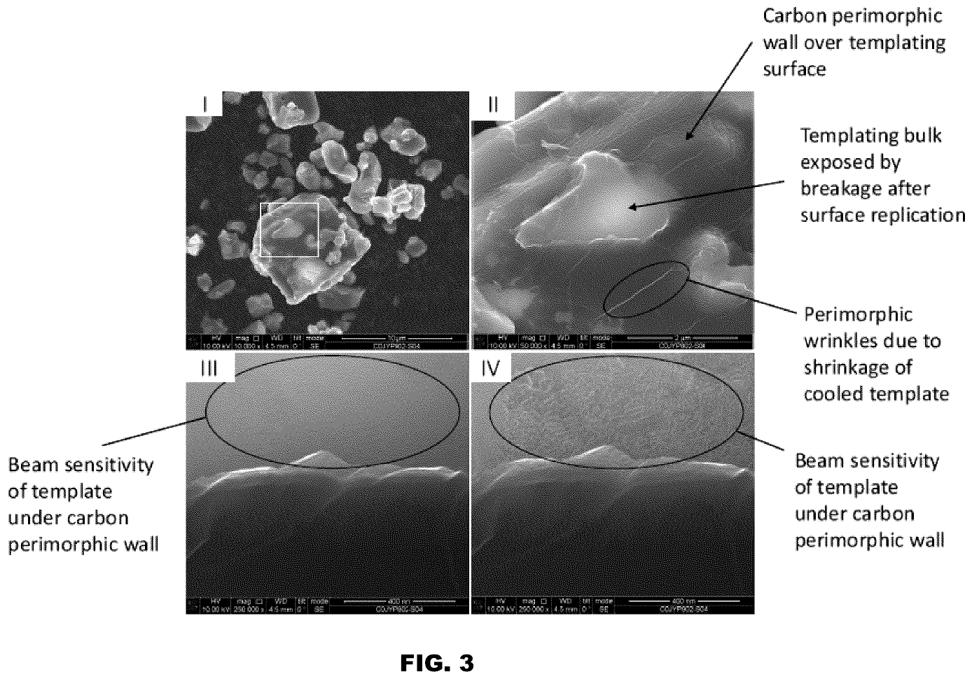

Frame I of FIG. 3 includes SEM micrographs of broken PC structures from Experiment 1 prior to endomorphic extraction. Many of the particles appear to have broken at junctions after the CVD procedure, as shown in the magnified micrograph of Frame II. In these regions, where the underlying oxyanionic template is not covered with a carbon perimorphic wall, more charging under the electron beam occurs due to the insulating behavior of the template. An exposed region of the underlying template at a broken junction can be distinguished from the surrounding regions due to its flat, charging surface. The darker areas around this exposed region represent areas in which the template is covered by the perimorphic wall. The presence of a flexible perimorphic wall can also be distinguished in Frame II by wrinkling, which can be attributed to shrinkage of the underlying template during cooling. At higher magnifications, the template underneath the perimorphic wall becomes beam sensitive, and this sensitivity with prolonged exposure can be seen in the SEM images in Frames III and IV. This beam sensitivity has never been observed in metal oxide templates and may be attributable to decomposition on or near the templating surface.

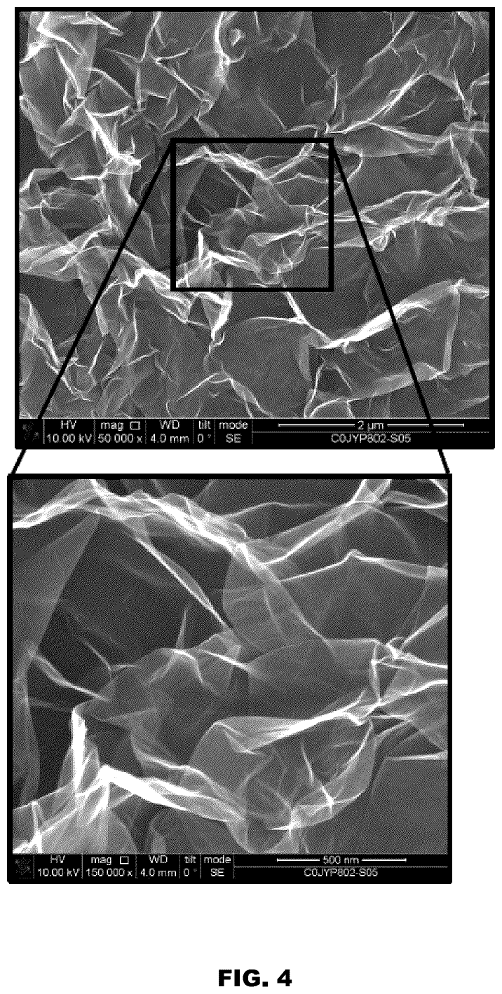

FIG. 4 includes SEM micrographs of the perimorphic frameworks from Experiment 1 after endomorphic extraction, rinsing, and drying. Consistent with the flexibility evident in the wrinkles in the carbon perimorphic walls shown in Frame II of FIG. 3, the perimorphic frameworks appear to have crumpled and adopted a non-native morphology after endomorphic extraction. It is noted, however, that many of the frameworks appear substantially unbroken and do not show extensive fragmentation. Therefore, they are likely “deflated” perimorphic frameworks. Over numerous experiments we have observed that many such deformed frameworks are deformed elastically and may spring back to their native, “inflated” morphology when filled with liquids. This is a useful attribute for many applications (e.g. absorption). Alternatively, these structures may be subjected to milling or high shear to produce large, sheet-like fragments, similar to nanoplatelets.

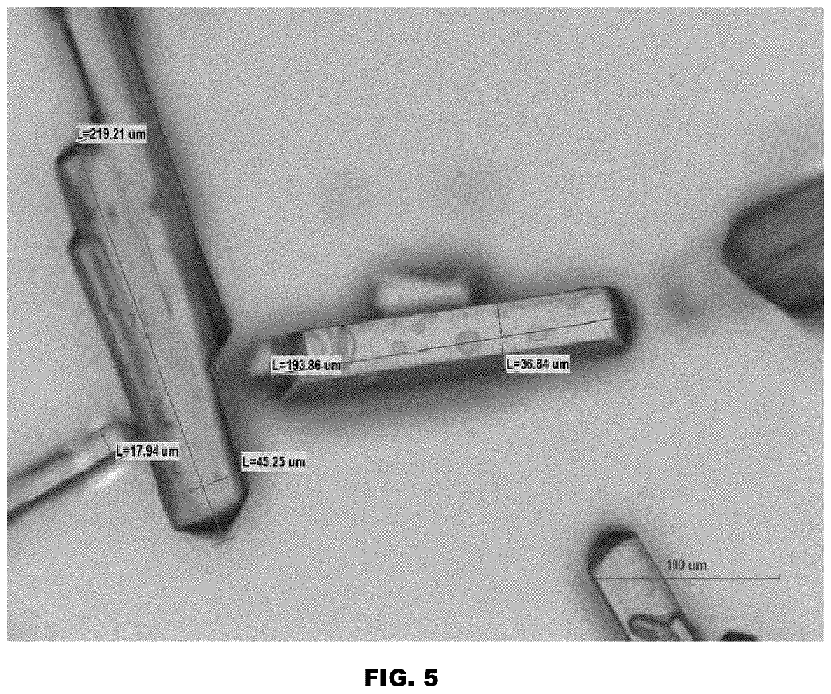

FIG. 5 shows the precipitated template precursor structures produced in Experiment 5 under optical microscope. These have also been reported in the '918 Application. The morphology is elongated and crystalline. Many of the particles are polycrystalline agglomerates.

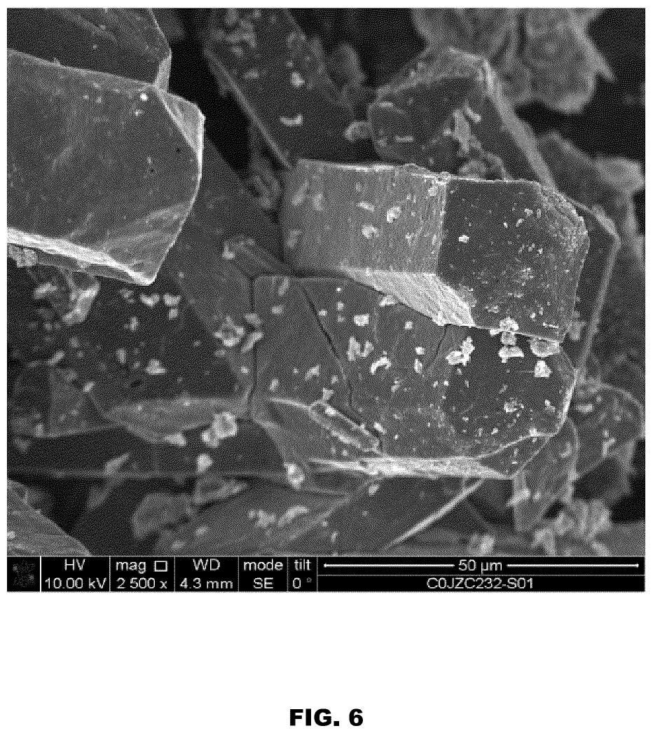

FIG. 6 is an SEM micrograph showing the PC material from Experiment 5 prior to endomorphic extraction. Debris can be seen on the surface of the perimorphic composite particles. This may be a result of shattering during dehydration. Dehydration of epsomite has been shown to cause fractures as crystalline water is evacuated. Based on SEM analysis of this PC material, the epsomite template precursor (MgSO₄·7H₂O) particles precipitated in Experiment 5 fractured during dehydration. While most particles were fractured to some extent, some particles appeared more fractured than others.

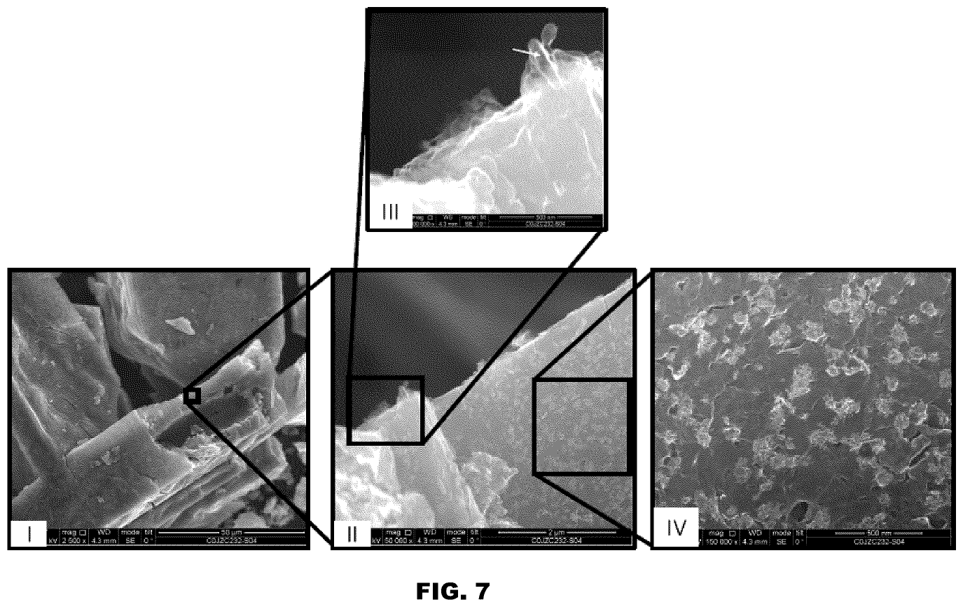

FIG. 7 includes SEM images showing the perimorphic frameworks from Experiment 5 after endomorphic extraction, rinsing, and drying. Unlike the frameworks produced in Experiment 1, many of these frameworks have substantially retained their native morphology and have a superstructure and substructure inherited from the template geometry. This can be discerned in the elongated carbon structures shown in Frame I of FIG. 7.

The inset of Frame I of FIG. 7 is shown at higher magnification in Frame II. Here, two phases are apparent. The first phase is the perimorphic carbon, the porosity of which can be discerned at higher magnification in Frame III. The translucent appearance of the perimorphic walls indicates a thickness of no more than several nanometers.

The second phase, which can be discerned at higher magnification in Frame IV of FIG. 7, is residual MgSO₄ on the surface of the perimorphic frameworks. The MgSO₄ residue charges under the electron beam. The presence of this residue can be explained by the high solute concentration of the aqueous solution created during endomorphic extraction of the high-solubility oxyanionic template, as well as the large amount of retained water in the three-dimensional perimorphic frameworks. Even after rinsing, the framework contained a significant amount of dissolved MgSO₄ that left a ubiquitous residue upon drying. This residue was not observed in Experiment 1 since the voluminous pores with in the perimorphic frameworks were collapsed and less water was retained in them.

The perimorphic frameworks produced in Experiment 5, while their walls were only a few nanometers in thickness, demonstrated a superior ability to retain their native morphology compared to the frameworks produced in Experiment 1. This is attributable to the compactness and associated rigidity of the cellular substructures of the frameworks produced in Experiment 5. Namely, surface replication techniques that utilize nonporous templates, or templates with no nanoscopic pores, will result in a less compact architecture than surface replication techniques that utilize templates with finer pore structures. In the case of Experiment 5, the MgSO₄ templates had finer internal pore structures due to the escape of crystalline water from the epsomite template precursor particles during heating. This is reflected in the substantial mass loss observed after thermal exposure, as shown in Table 2. In the case of Experiment 1, the K₂SO₄ was anhydrous, and no internal pore structure was evolved during thermal exposure.

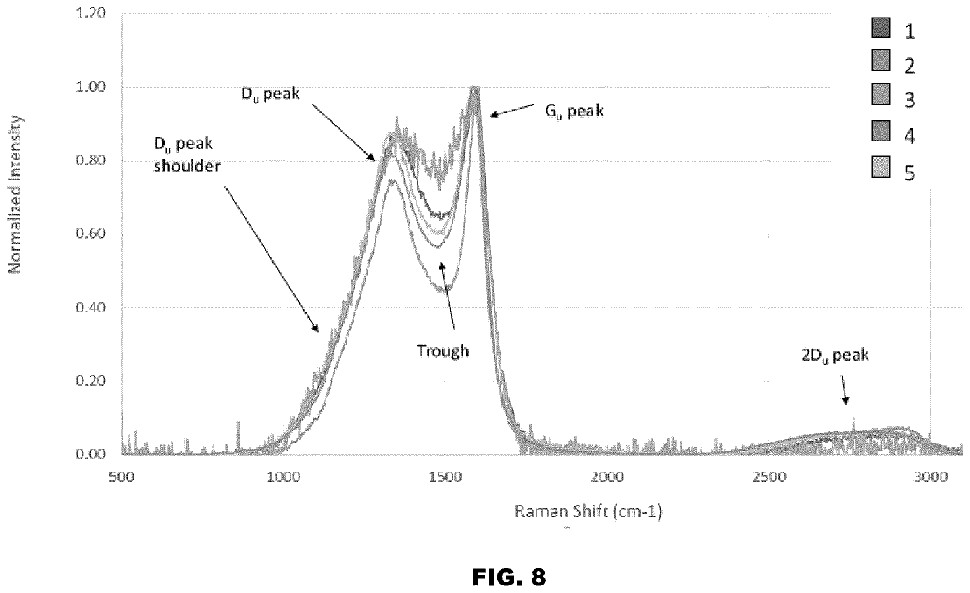

FIG. 8 presents the averaged Raman spectra for each of the perimorphic carbon materials synthesized using the oxyanionic templates in Study A. Each sample was first purified via endomorphic extraction and rinsing, such that only the carbonaceous perimorphic frameworks were analyzed. The spectra in FIG. 8 are labeled 1 through 5 according to the experiment to which they pertain (i.e. Experiments 1 through 5). The spectra confirm the presence of disordered sp²-hybridized carbon in each of the samples, and synthetic anthracitic networks in Experiments 1, 2, 4, and 5. The spectral peak ratios and locations are summarized in Table 3 below:

TABLE 3
Average Raman spectral data for
carbon samples (Experiments 1-5).

| | | | | D peak | G peak |
|---|---|---|---|---|---|
| Experiment | | | | pos. | pos. |
| No. | I_{D}/I_{G} | I_{Tr}/I_{G} | I_{2D}/I_{G} | (cm⁻¹) | (cm⁻¹) |
| 1 | 0.87 | 0.64 | 0.06 | 1336 | 1594 |
| 2 | 0.75 | 0.44 | 0.07 | 1331 | 1601 |
| 3 | 0.92* | 0.79* | 0.03* | 1354* | 1587* |
| 4 | 0.82 | 0.56 | 0.07 | 1331 | 1585 |
| 5 | 0.88 | 0.60 | 0.10 | 1328 | 1583 |

*Derived from smoothed average spectrum

Sp² hybridized carbon is indicated by the presence of the Gᵤ peak (with point spectra ranging between 1580 cm⁻¹ and 1610 cm⁻¹) and the Dᵤ peak (with point spectra ranging between 1320 cm⁻¹ and 1360 cm⁻¹). Disorder is indicated by various spectral features, including the absence of a significant 2Dᵤ peak, the breadth and low peak intensity of the Dᵤ peak, and the height of the trough between the D band and the G band. While the Dᵤ peak intensity is not by itself an indication of disorder, since low-intensity Dᵤ peaks can also be found in crystalline graphitic carbons, it indicates a high degree of disorder in the context of these other spectral features. The trough, which is herein attributed to red-shifted modes of the Gᵤ peak, reflects the stretching and twisting of C(sp²)-C(sp²) bonds in disordered lattices. Prolific ring disorder will cause a broad distribution of lower-frequency strain states, and the G peak position is known to be strain-dependent. Since I_{Tr}/I_{G} would be close to zero in relatively defect-free graphite, this result further suggests that each sample has a relatively high defect concentration.

The spectra in Experiments 1, 2, 4, and 5—and in particular the red-shifted position of their Dᵤ peaks indicate that the perimorphic carbons in these samples comprise sp^{x} networks, which are a type of synthetic anthracitic network comprising both sp²-hybridized and sp³-hybridized states. A more comprehensive description of this type of anthracitic network, and the spectral signatures accompanying it, are provided in the '37435 Application. While the D band of sp² carbons is dispersive, and D peak positions can shift based on excitation, the average Dᵤ peak positions observed in Experiments 1, 2, 4, and 5 are significantly lower than the Dᵤ peak position typically associated with sp² carbon under 532 nm excitation (around 1350 cm⁻¹). This red-shifting indicates underlying interpolation of the sp² vibrational density of states (VDOS) with lower-frequency bands found in the sp³ VDOS.

Interpolation of the VDOS in an alloy structure occurs when there is strong coupling between the phases. Interpolation between the D band (associated with sp² hybridization) and lower-frequency bands indicates the strong coupling of sp³ states and sp² states in their immediate proximity. These regions of strong coupling activate the radial breathing mode (“RBM”) phonons found throughout the graphenic system's entire sp² ring structure. Hence, even a trace-level presence of sp³ carbon states can be discerned in the Raman spectrum due to their activation of RBM phonons that are found throughout the much larger sp² component.

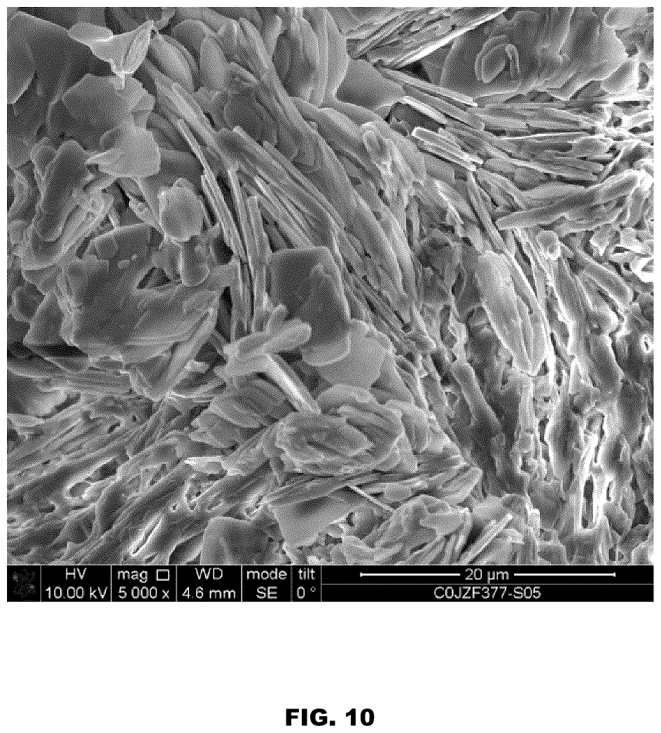

In Experiment 3, the Dᵤ peak does not appear interpolated with lower-frequency sp³ bands; this is likely due to the absence of tectonic encounters in the area characterized by the Raman analysis. In regions where there are no tectonic encounters between neighboring nuclei and consequently no sp³ grafting across tectonic interfaces, few if any C(sp³)-C(sp³) bonds are to be expected. If present, they are nevertheless few in relation to other defects when compared to regions where tectonic encounters are numerous and sp³ grafting is prolific. Therefore, the lack of observable interpolation of the Dᵤ peak in Exp. 3 can be attributed to regions where nucleation is scarce or absent-regions with few or no reactive sites. This makes sense given the large, atomically flat facets characterizing the K₂CO₃ templating surfaces and points to surface defects as the reactive sites where nucleation occurs, similar to oxide surfaces. The flat K₂CO₃ facets can be seen in FIG. 10, an SEM image of the PC material generated in Experiment 3.

Other spectral differences in the sample from Experiment 3 are the noisiness of the spectrum and the significantly higher trough. The higher trough is attributable to the prolific ring disorder produced via FRC growth over the large facets without many tectonic encounters. In the '37435 Application, we describe in more detail how tectonic encounters between laterally adjacent graphenic regions lead to grafting and coalescence, which in turn leads to intralayer compressive strain. The intralayer compressive strain causes blue-shifting of the Gᵤ peak, which can shift to 1600 cm⁻¹ and higher, and a reduction in the height of the trough, since the trough is attributed to stretched C(sp²)-C(sp²) bonds. Therefore, the higher trough observed in Experiment 3 is in good agreement with the un-interpolated Dᵤ peak position and corroborates the presence of ring disorder and the absence of sp³ grafting along large, defectless facets, which in Experiment 3 dominate the templating surfaces.

Experiments 1-5 demonstrate the formation of perimorphic frameworks comprising synthetic anthracitic networks-including sp^{x} networks with various degrees of grafting on oxyanionic templates. These frameworks can be matured into helicoidal networks using annealing processes such as those described in the '37435 Application. These annealing processes can be performed on the PC material or after endomorphic extraction based on application requirements. The oxyanionic templates can be readily dissolved in water or aqueous oxyanion-bearing solutions such as carbonic acid.

Numerous other oxyanionic species and oxyanionic template structures may be utilized in addition to the exemplary templates in Experiments 1 through 5. Using CVD procedures similar to those described in Experiments 1 through 5 (e.g. flowing C₃H₆ and Ar at a temperature of 750° C.), we have synthesized perimorphic carbons on sodium aluminate (NaAlO₂, melting point 1650° C.) and sodium metasilicate (NaSiO₃, melting point 1088° C.) templates. By spray-drying the template precursor material, oxyanionic templates of various chemical compositions may be engineered with spherical or hollow morphological features. In the '53316 Application, the P₁₈-type perimorphic carbons with a hollow, spherical morphology were grown via CVD on Li₂CO₃ templates at 580° C. with no signs of melting and minimal mass loss (<1.5%) after CVD. This indicates that oxyanionic templates represent a rich library of potential template materials with diverse properties.

If the perimorphic walls are kept thin by limiting CVD growth time, crumpled and sheet-like structures can also be formed, and these can be filtered, or dried on a substrate (e.g. a glass slide) to form lamellar, buckypaper-like macroforms cohered via van der Waals forces. Unlike other nanostructured carbons like graphene oxide or carbon nanotubes that are generally utilized to form buckypapers, though, these graphenic perimorphic structures do not need to be oxidized or treated with chemical dispersants to disperse them and prevent them from flocculating prior to filtration or drying.

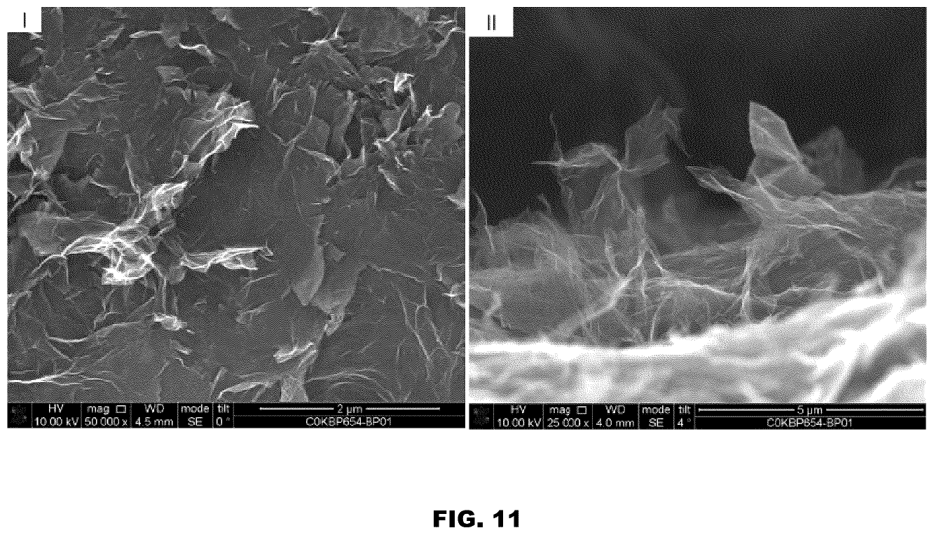

For example, using an exemplary procedure similar to Experiments 1-5 (e.g. a spray-dried powder of spherical Li₂CO₃ template precursor particles, heated to a CVD temperature of 580° C., and exposed to flowing C₃H₆ and Ar gas for 180 minutes), a C@Li₂CO₃ PC material was formed. After an aqueous endomorphic extraction of the Li₂CO₃ template, the anthracitic perimorphic frameworks were filtered to form a buckypaper-like lamellar macroforms without the use of oxidation or dispersants. Top-down and horizontal views of one such macroform are shown in Frames I and II of FIG. 11, respectively.

The ability to form these buckypaper-like macroforms is due to a morpho-dispersibility property in liquids that does not depend on compatibilizing the particles' surface chemistry with the liquid matrix via chemical functionalization or use of dispersants. Instead, the frameworks self-disperse due to their morphology, which comprises large pores that are semi-encapsulated by the flexible perimorphic framework. When these internal pores are impregnated by an external liquid, the liquid becomes entrained, and the liquid-filled frameworks behave like bulk-phase particles. This is because the ratio of their outer surface area to their total effective mass, which includes the mass of entrained liquid, is similar to bulk-phase materials, despite their nanostructured perimorphic walls.

The morpho-dispersibility of liquid-filled perimorphic frameworks keeps them from forming dense, stable agglomerates in liquids. In addition to facilitating the synthesis of lamellar, buckypaper-like macroforms and coatings, the morpho-dispersibility of liquid-filled perimorphic frameworks makes these nanostructured materials appealing for nanofluids. Furthermore, this property is not exclusive to carbonaceous perimorphic frameworks. Because morpho-dispersibility is a function of morphology, other nanostructured perimorphic materials—for example, the BN or BCₓN frameworks demonstrated in the '53316 Application may also be ideal for synthesizing nanofluids or buckypaper-like macroforms.

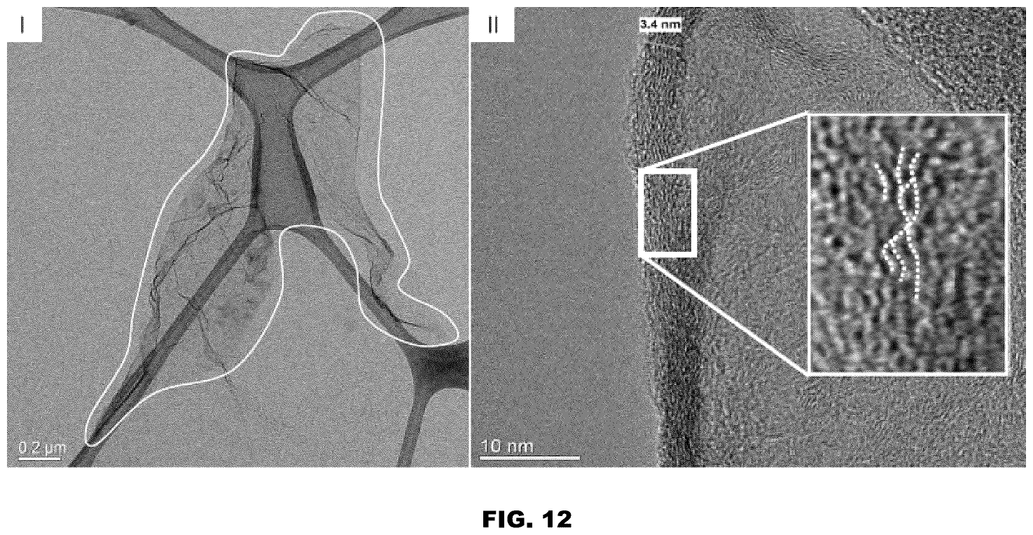

FIG. 12 includes TEM micrographs of a sheet-like fragment of a perimorphic framework grown on Li₂CO₃. The perimorphic carbon is the translucent, crumpled film labeled via white outline in Frame I. Several wrinkles can be seen in the perimorphic carbon, indicating its thinness and flexibility-both desirable qualities for constructing lamellar buckypapers. Frame II, a higher-resolution TEM micrograph, shows the layered architecture of the perimorphic wall, which measures several nanometers in thickness. The graphenic layers, some of which are traced with white dotted lines, are nematically aligned due to their conformal growth over the templating surface, but the layers are also clearly nonplanar and networked. This layered, connected network structure is typical of anthracitic networks when characterized using high-resolution TEM.

This application discloses several numerical ranges in the text and figures. The numerical ranges disclosed support ranges or values within the disclosed numerical ranges, even though a precise range limitation is not stated verbatim in the specification, since this disclosure can be practiced throughout the disclosed numerical ranges.

The above description is presented to enable a person skilled in the art to make and use the disclosure. Various modifications to the embodiments will be readily apparent to those skilled in the art, and the generic principles defined herein may be applied to other embodiment and applications without departing from the spirit and scope of the disclosure. Thus, this disclosure is not intended to be limited to the embodiments shown but is to be accorded the widest scope consistent with the principles and features disclosed herein. Finally, the entire disclosure of the patents and publications referred to in this application is hereby incorporated herein by reference.

1. A method for producing nanostructured materials, the method comprising:
Flowing a chemical vapor over a surface of a substrate, the substrate comprising oxyanions and the substrate's surface comprising one or more reactive sites; and
Reacting the chemical vapor with the substrate at the one or more reactive sites to deposit an adsorbate; and
Reacting the chemical vapor with the adsorbate to grow the adsorbate, the growing adsorbate forming a nanostructured material conforming to the substrate's surface.

2. The method of claim 1, wherein the substrate comprises a template, the template comprising a templating surface and a templating bulk.

3. The method of claim 1, further comprising heating the chemical vapor to a temperature between 400° C. and 1,000° C.

4. The method of claim 2, wherein the template comprises an oxyanionic template particle with a maximum diameter of 1 cm.

5. The method of claim 4, wherein the oxyanionic template comprises at least one of a borate, bromate, perbromate, bromite, hypobromite, chlorate, perchlorate, chlorite, hypochlorite, hydroxide, periodate, iodate, iodite, hypoiodite, carbonate, bicarbonate, nitrate, nitrite, phosphate, biphosphate, phosphite, sulfate, thiosulfate, bisulfate, sulfite, bisulfite, chromate, chromite, dichromate, iodate, iodite, manganate, permanganate, manganite, arsenate, arsenite, ferrate, silicate, aluminate, aluminosilicate, selenate, selenite, tungstate, vanadate, tellurate, tellurite, titanate, molybdate, acetate, citrate, benzoate, oxalate, tartrate, and gluconate.

6. The method of any claim herein, wherein the oxyanionic template comprises a Group I or Group II metal cation.

7. The method of claim 4, wherein the templating surface of the oxyanionic template comprises oxygen anions.

8. The method of claim 4, wherein the oxyanionic template comprises at least one of a melting point between 400° C. and 800° C. and a melting point between 800° C. and 1200° C.

9. The method of claim 4, wherein the oxyanionic template is derived from an oxyanionic template precursor.

10. The method of claim 4, wherein the oxyanionic template comprises a porous structure.

11. The method of claim 4, wherein the oxyanionic template is soluble in water.

12. The method of claim 4, wherein the oxyanionic template forms a soluble compound when reacted with water.

13. The method of claim 4, wherein the adsorbate comprises a free radical condensate.

14. The method of claim 4, wherein the chemical vapor comprises at least one of free radicals, hydrogen, a hydrocarbon, and a hydroboron.

15. The method of claim 4, wherein the nanostructured material comprises a perimorph, the perimorph substantially surrounding the template, the templating comprising an endomorphic solid.

16. The method of claim 15, wherein the perimorph replicates at least one of a size, shape, topography, and topology of the templating surface.

17. The method of claim 15, wherein the perimorph comprises a synthetic anthracitic network.

18. The method of claim 17, wherein the synthetic anthracitic network comprises carbon.

19. The method of claim 18, wherein the carbon comprises at least one of an sp^{x} network, a helicoidal network, an x-carbon, a z-carbon, a lattice-engineered carbon, a disordered carbon.

20. The method of claim 15, further comprising
Exposing the endomorphic solid to a liquid extractant to:
extract the endomorphic solid from the surrounding perimorph via dissolution; and
form pores within the perimorph via the extracting of the endomorphic solid, the perimorph and pores comprising a perimorphic framework.
